(19) United States
(12) Patent Application Publication
(10) Pub. No.: US 2009/0212665 A1
(43) Pub. Date: Aug. 27, 2009

(54) Power harvesting scheme based on piezoelectricity and nonlinear deflections

(76) Inventors: Hur Koser, New Haven, CT (US); Nian Zhang, Syosset, NY (US)

Correspondence Address: ARTHUR G. SCHAIER;CARMODY & TORRANCE LLP, 50 LEAVENWORTH STREET, P.O. BOX 1110, WATERBURY, CT, 06721, US

(21) Appl. No.: 11/887,015

(22) PCT Filed: Mar. 23, 2006
(86) PCT No.: PCT/US2006/010447

§ 371 Date: Oct. 29, 2008

Related U.S. Application Data
(60) Provisional application No. 60/665,226, filed on Mar. 24, 2005.

(51) Int. Cl. H02N 2/18; H01L 41/04; F03G 7/08

(52) U.S. Cl. 310/339; 310/351

(57) ABSTRACT

An energy harvesting device and a method of using the energy harvesting device to generate an electrical charge are described. The energy harvesting device comprises a mass and at least two tethers, at least one of which comprises a piezoelectric material that is mechanically stressable upon deflection of the at least two tethers. Each of the tethers comprises a first end coupled to the mass and a second end coupled to a reference structure, and the tethers are arranged about the mass such that the mass is moveable within a straightline path relative to the reference. The movement of the mass causes the deflection of the tethers, resulting in the generation of an electric charge. The device is preferably operable at the microscale.

### CROSS REFERENCE TO RELATED APPLICATIONS

This application claims the benefit of U.S. Provisional Application No. 60/665,226, filed Mar. 24, 2005, the subject matter of which is herein incorporated by reference in its entirety.

### FIELD OF THE INVENTION

The present invention is directed to an energy harvesting device.

### BACKGROUND OF THE INVENTION

Energy harvesting involves the use of ambient energy sources to produce power. Using ambient energy sources to produce power may allow the use of self-powering circuits and enables the use of low power sensing monitoring, communication, computation, actuation and control applications. Harvesting energy from ambient energy sources is especially useful for long-term remote applications that would otherwise require multiple battery replacements. Mechanical vibration is a potential power source that is converted into electrical energy through microelectromechanical systems (MEMS) technology. Ambient vibration energy sources include, for example, car engine compartments, car instrument panels, a door frame just after a door closes, blender casings, clothes dryers, small microwave ovens, HVAC vents in office buildings, windows near a busy road, CDs on a notebook computer, and the walls of a busy office building, among others.

Examples of energy harvesters that are currently in use include solar panels (used in display panels and water heating systems), light panels (used in calculators), shoe inserts (used in military applications), electromagnetic fields (used in radio frequency identification device (RFID) tags), and vibrations (used in tire pressure sensors, for monitoring motor vibrations and for building monitoring).

Vibration energy harvesters can be based on electromagnetic, electrostatic or piezoelectric mechanisms. Electromagnetic mechanisms function by the relative motion between a wire coil and a magnetic field which causes a current to flow in the coil. One of the advantages of electromagnetic mechanisms is that no voltage source is needed to get the process going; however, a disadvantage is that the output voltage is limited to about 0.1-0.2 volts. Electrostatic mechanisms use a variable capacitor, and the maximum capacitance determines the maximum output voltage. Electrostatic mechanisms have the advantage of being easier to integrate into Microsystems, but disadvantages resulting from the low breakdown voltage between the capacitor plates typically limit the energy levels harvested. For maximum energy extraction capacitance change needs to be maximized at each oscillation cycle, which requires the plates to be as close to each other as possible. On the other hand, if the plates are too close together or if the voltage gets too high, air will breakdown and temporarily conduct, resulting in the loss of the charge that was stored in the capacitor.

Piezoelectric materials are ideal candidates for harvesting power from ambient vibration sources because they can efficiently convert mechanical strain to an electrical signal. Piezoelectric mechanisms function by using a stress change to generate a voltage. With piezoelectric devices, voltage source is needed to initiate energy extraction, and an output voltage of about 1-8 volts can be generated. However, a disadvantage is that conventional piezoelectric mechanisms can be somewhat difficult to integrate into microsystems.

A self-powering sensor arrangement with wireless communication would greatly minimize the complexity and cost of monitoring and control while at the same time enhancing reliability and flexibility. Because vibration energy is mostly present at low frequencies and large amplitudes (tens of microns or more), it would be desirable to incorporate the sensor arrangement with a novel piezoelectric energy harvester to create a device that stores energy from the ambient deflections at a given low frequency in an optimal manner. This typically requires large nonlinear deflections.

MEMS accelerometers function by detecting the deflections of a proof mass, suspended from a frame via relatively compliant tethers. The detection of the proof mass deflections may be achieved via capacitive, piezoelectric, or tunneling current sensors, and the devices are designed to operate linearly and for maximum sensitivity within the intended levels of input acceleration values. However, when the input acceleration is far beyond the design specifications, such as when the device is unintentionally dropped on a hard surface, the acceleration of the proof mass may be several thousand times the gravitational acceleration (g), resulting in a very large deflection amplitude that bends the tethers in a nonlinear fashion. Normally, this can cause enormous stress concentration on the ends of the tether, and structural failure of the device may result.

The inventors of the present invention have determined that the presence of a piezoelectric thin film on certain sections of the tethers can change the dynamics somewhat and reduce the maximum stress that the tether bases can be subject to. The proposed system of the invention allows the mechanical structure to not only bend, as is customary in linear designs, but also to stretch in response to external vibrations. The stretching results in a nonlinear relationship between the beam deflection and the resulting stress magnitude on its surface.

In contrast, cantilever beams, which have been used previously in energy harvesting devices, are designed for linear deflections, which limits the deflection amplitude to less than the beam thickness. Even if the cantilever beam structure undergoes stretching in large magnitude deflections, the resulting large stresses are still localized to its base. In order to obtain large stress magnitudes over essentially the entire surface of the mechanical transducer (for maximum piezoelectric material coverage), a clamped-clamped structure is necessary.

Other ways of harvesting energy, especially at the micro-scale, have focused on capacitative (electrostatic) or magnetic schemes. However, typical device sizes that can achieve microWatts of energy are on the order of centimeters, and scaling these devices to smaller sizes reduces the power harvested accordingly.

In order to harvest the maximum energy possible, the deflection amplitude of the suspended mass needs to be maximized and the frequency should be as high as possible. Correspondingly, energy harvesting schemes previously reported are typically resonant around a few kHz to a few tens of kHz. The suspended masses used in these systems are large, bulky and do not contribute to the physical process of voltage generation besides providing a large mass. Unfortunately, the ambient vibrations present at these high frequencies are miniscule, and the resonant approach ensures that these devices are completely custom suited for only a very narrow range of applications. What is needed is an energy harvester that can effectively harvest energy at the low and variable vibration frequencies of buildings, bridges, cars, engines and even the ground, including by way of example and not limitation:
Car engine compartment
Base of 3-axis machine tool
Blender casing
Clothes dryer
Person tapping their heel
Car instrument panel
Door frame just after door closes
Small microwave oven
HVAC vents in office building
Windows next to a busy road
CD on notebook computer
Floors of busy office buildings.

### SUMMARY OF THE INVENTION

It is an object of the present invention to provide an improved energy harvesting device that is usable to harvest energy, especially at the micro-scale level.

It is another object of the present invention to provided an improved an energy harvesting device that is based on piezoelectric materials.

It is another object of the present invention to provide a mechanical structure that is capable of stretching as well as bending in response to external vibrations and that works in a non-linear deflection regime.

It is still another object of the present invention to provide an improved energy harvester for using ambient vibrations to generate an electrical charge.

It is yet another object of the present invention to provide an improved energy harvesting device that includes at least one sensor or other powerable device for sensing an external parameter or observing an external condition.

To that end, in a preferred embodiment, the present invention is directed to an improved energy harvesting device that comprises:

a) a mass; and
b) at least two tethers, at least one of which comprises a piezoelectric material that is mechanically stressable upon deflection of the at least two tethers, wherein each of the at least two tethers comprise a first end coupled to the mass and a second end coupled to a reference, wherein the tethers are arranged about the mass such that the mass is moveable within an essentially straightline path relative to the reference;

whereby the movement of the mass causes the deflection of the at least two tethers thereby resulting in the generation of an electric charge.

In an alternate embodiment, the present invention is directed to an energy harvesting device that comprises:

a mass; and

a means coupled to the mass and to a reference, wherein the means comprises a piezoelectric material that is mechanically stressable upon deflection and wherein the means are arranged about the mass such that the mass is moveable within an essentially straightline path relative to the reference;

whereby, the movement of the mass causes the stressing of the piezoelectric material thereby resulting in the generation of an electric charge.

In yet a third embodiment, the present invention is directed to a method of storing an electrical charge in an energy harvesting device comprising a mass; at least two tethers, at least one of which comprises a piezoelectric material that is mechanically stressable upon deflection of the at least two tethers, wherein each of the at least two tethers comprise a first end coupled to the mass and a second end coupled to a reference, wherein the tethers are arranged about the mass such that the mass is moveable within an essentially straightline path relative to the reference, wherein the method comprises the steps of:

a) moving the mass to cause the deflection of the at least two tethers and generate an electrical charge; and

b) storing the electrical charge generated by movement of the mass.

### BRIEF DESCRIPTION OF THE FIGURES

For a fuller understanding of the invention, reference is had to the following description taken in connection with the accompanying figures, in which:

FIG. 1 depicts a top or plan view of the energy harvesting device of the present invention.

FIG. 2 demonstrates the stress distribution over the surface of tether along its length.

FIG. 3 depicts stress and voltage values along the length of a cantilever beam.

FIG. 4 depicts another view of the energy harvesting device of the present invention.

Identical reference numerals in the figures are intended to indicate like features, although not every feature in every figure may be called out with a reference numeral.

### DETAILED DESCRIPTION OF THE PREFERRED EMBODIMENTS

The present invention encompasses a micro-scale piezoelectric power harvesting device, similar in design to MEMS piezoelectric accelerometers. A mass is suspended by thin flexural beams from a reference (such as a frame). The base of the frame may be couplable or contactable with or is otherwise in an environment that has ambient vibrations (e.g., the wall of a building, an engine or a motor, inside of a car tire, etc.). As the frame oscillates, the mechanical vibrations are transferred to the suspended mass. In the preferred embodiment, the beams have piezoelectric material on their surfaces. As the beams flex, the piezoelectric material converts oscillatory mechanical stress into oscillatory electric voltages. If a storage capacitor is used to collect the electrical charge, electrical energy can be extracted from the mechanical oscillations. This energy can then be used to power integrated sensors or transmitters, or the like, depending on the target application.

The present invention works in a completely nonlinear deflection regime (as opposed to a linear resonant scheme) that allows for the extraction of significant power even at lower frequencies. The key is to stretch the flexural beams many times their thickness (as in a guitar string being plucked very hard). This way, the stress induced on the piezoelectric material is tens of times larger than the maximum stress that can be induced using a resonant approach. In addition, unlike with the resonant approach, this stress is not limited to the ends of the beams. For a deflection larger than a few times the beam thickness, the majority of the stress energy over most of the surface is due to stretching, which is tensile, while at either clamped end, there is additional stress due to either tensile or compressive bending. Due to stretching, the large stress is present everywhere along the beams. Thus, almost all the surface area of the flexural beams will contribute to voltage generation, significantly increasing the power that can be harvested.

By utilizing the large vibrations present at low frequencies in the ambient environment, these devices can become commercially viable for all kinds of different applications. The devices are typically fabricated out of silicon using MEMS fabrication techniques, and the top surface of the suspended mass is an ideal place for integrated electronics, memory, control circuitry and sensors, making the device one of the most compact of its kind. The utilization of nonlinear deflection dynamics (i.e., the stretching of the beams as opposed to their bending) allows for maximum stress utilization and an energy harvesting scheme that can generate electrical energy orders of magnitude larger than similar schemes operating at the same frequencies.

The present invention envisions 1 mm cube or smaller devices that use the ambient vibrations to power an integrated sensor node (such as a stress sensor, a microphone, etc.). Depending on the desired application, these devices may also be scaled up to the centimeter range. These devices can be made at a low cost (i.e., for cents a piece), making it feasible for thousands of them to be integrated into the cement and other structural components of buildings and bridges during construction. These devices can last inside the structure functioning for up to 50 years, continuously monitoring stress levels and signaling any deviations from normal to a central network node. Their exact locations inside the structure can be triangulated using all the devices as a sensor network. In this fashion, micro-fractures and other stress points not readily observable from the outside can be pinpointed and life saving precautions can be taken years before the structure actually fails.

The devices of the invention may have applications in border patrol or homeland security. Indistinguishable from the sand or soil grains in the environment, the devices can be deployed at a site that needs to be continuously monitored. Any activity (i.e., a vehicle crossing, movement of individuals, etc.) can be detected and signaled to a central location without the need to change batteries or service the devices. In a sense, the devices are intended to function as a “perform/deploy/forget” type of device.

Another commercial application is in continuous wireless monitoring of car (or other vehicle) tire pressure changes. As soon as the engine starts, these devices have enough vibrations to harvest their power from and begin reporting on the current state of car tire pressure.

Yet another commercial application may involve coupling one or more of these devices to a fragile package to ensure a recipient that the delivery process of a given package has not resulted in a physical shock to the contents of that package. For instance, a computer manufacturer may want to ensure that from the factory to the end user, the computer being shipped did not see any major vibrations or physical abuse (i.e., it was not dropped) or a person shipping perishable goods may want to ensure that the goods were not exposed to extreme temperatures. By providing a sensor that monitors such vibratory or temperature conditions in connection with an inexpensive yet sufficiently efficient energy harvester, such capability is now a reality.

Another application of the invention involves turning mobile insects, such as honeybees, into wireless sensor or communication nodes by strapping one or more energy harvesting devices to their backs. This has been attempted previously within systems based on battery power to wire up the insects with sensors for various monitoring applications. However, by providing the insect with an energy harvesting device of the present invention in combination with a sensor or other device (e.g. camera), the requirements for size, power density, and the integration necessary to implement this idea is achieved.

Devices that incorporate the energy harvesting device of the present invention may also function as smart tags, similar to RFID tags. In addition, RFID tags can also be integrated into energy harvesting devices of the present invention. Thus, instead of only presenting an identification number every time it is inquired by a radio frequency pulse, these tags can actually store and upload the entire history and associated side information from the manufacturer about the specific product. This would be possible, because the energy harvesting devices of the invention would have a small amount of integrated memory, and the energy generated from vibrations during shipment would be sufficient to store new information every couple of minutes.

The mechanical components of the preferred energy harvesting device are typically fabricated out of silicon using standard MEMS fabrication processes, such as bulk micromachining. A proof mass of silicon provides the necessary mass and can also support on its surface one or more of Complementary Metal-Oxide Semiconductor (CMOS) circuitry for power extraction, sensing and wireless transmission, and a small storage capacitor (i.e., a few nanoFarads), which may cover most of the surface of the proof mass. The device of the invention can be customized for the needs of different sensing, monitoring, and control applications. In addition, if a larger external storage capacitor and/or a larger antenna are required for long range communications, for example, they can be easily attached to the external packing of the device of the invention.

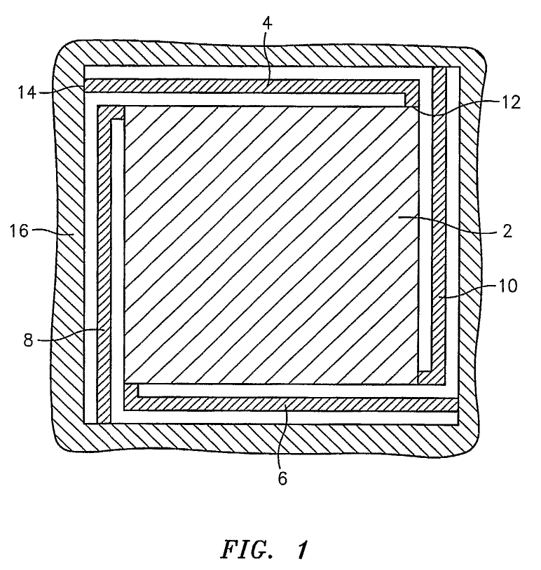

In a broad sense, as depicted in FIG. 1, in a preferred embodiment the present invention is directed to an energy harvesting device, comprising:

a) a mass 2; and
b) at least two tethers 4 and 6, at least one of which comprises a piezoelectric material that is mechanically stressable upon deflection of the at least two tethers, wherein each of the at least two tethers 4 and 6 comprise a first end 12 coupled to the mass 2 and a second end 14 coupled to a reference 16, wherein the tethers 4 and 6 are arranged about the mass 2 such that the mass 2 is moveable within an essentially straightline path relative to the reference 16;

whereby the movement of the mass 2 causes the deflection of the at least two tethers 4 and 6 thereby resulting in the generation of an electric charge.

In an alternative embodiment, an energy harvesting device of the present invention may comprise a mass and a means coupled to the mass and to a reference, wherein the means comprises a piezoelectric material that is mechanically stressable upon deflection and wherein the means are arranged about the mass such that the mass is moveable within an essentially straightline path relative to the reference. The movement of the mass causes the stressing of the piezoelectric material thereby resulting in the generation of an electric charge.

Preferably, the at least two tethers 4 and 6 are at least partially covered by the piezoelectric material. The type of piezoelectric material is not critical to the operation of the invention and various piezoelectric materials would be well known to those skilled in the art for use in the invention.

It is generally preferred (but not necessarily required) that both of the at least two tethers 4 and 6 comprise a piezoelectric material that is mechanically stressable, such that the mechanical stress of the piezoelectric material caused by the movement of the mass 2 generates an electric charge. It is generally preferably that the at least two tethers 4 and 6 be symmetrically positioned about the mass 2.

On a first side, the mass may be constructed to support CMOS circuitry, and both the mass and the tethers may be at least partially covered with the piezoelectric thin film. On a second side of the mass opposite of the first side, the mass surface is capable of supporting additional circuitry including by way of example and not limitation, a solar cell for additional environmental energy harvesting.

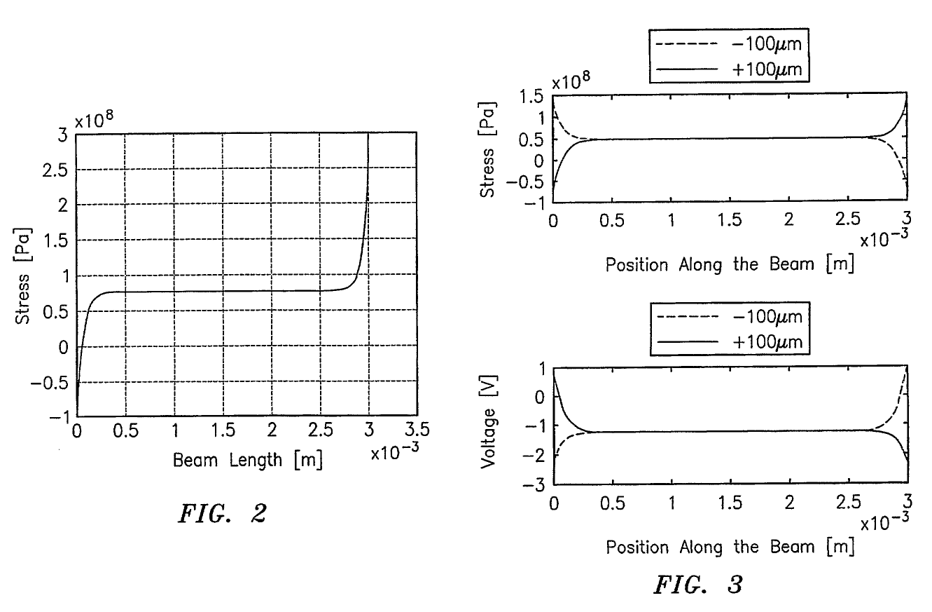

For large nonlinear deflections, stretching stress dominates over bending stress over most of a tether's surface, except near the clamped ends. FIG. 2 shows the stress distribution over the surface of a 5 μm thick tether along its length. For a 3 mm long tether, there is a 2.5 mm section in the middle where the stress is uniform and due almost entirely to stretching. Thus, it is preferable that the piezoelectric thin film be placed at the entire section of the tether where stress is uniform for a given mass deflection. In a preferred embodiment, the piezoelectric thin film is placed over at least 80 percent of the tether surface.

The piezoelectric material covering the wide middle section of the at least two tethers also produces only a single polarity voltage. This is because the stretching stress in that region is always tensile, regardless of the deflection direction of the proof mass. This is depicted in FIG. 3. As depicted in FIG. 3, a 5 μm thick, 6 mm long silicon beam was covered with a 2 μm thick piezoelectric layer and deflected from its center, resulting in positive and negative displacements. Except near the ends, the entire beam volume is in tension due to stretching for both positive and negative deflections. Both the displacements caused polarity of stress and voltage in the middle section.

Thus, the majority of the mechanical stressing of the piezoelectric material is due to stretching of the material, and most of the stored potential energy is in the stretching. Therefore if a piezoelectric thin film is deposited over this area where the axial surface stress is uniform, a large positive voltage will be produced. As compared to the linear designs of the prior art, the surface area of the piezoelectric material available in the approach of the invention is at least ten times larger.

Another significant advantage to the device of the invention is that it operates away from resonance, and thus requires no frequency tuning. The structure can be designed so that the lowest linear resonance frequencies are all below 50 Hz. The next resonance after that would then be beyond 3 kHz, so the operating bandwidth of the devices of the invention (from about 50 Hz to about 3 kHz) is orders of magnitude larger than those of linear designs that need to be operated very near resonance.

Preferably, the device of the invention is designed compliant enough to result in a first set of resonances much below the operating frequency, and the mass deflection amplitude would then be the deflection amplitude. The second set of resonances is typically in the range of many kHz. One of the benefits of the device of the present invention is that its operation can be tailored to a wide frequency range, which can cover virtually all practical mechanical vibration sources.

In one embodiment of the invention, the mass 2, when viewed in a top plan view such as that of FIG. 1, has four sides. In this instance, the first end 12 of the first tether 4 is coupled to one of the four sides and the first end of the at least second tether 6 is coupled to a side opposing the first side. The device of the invention may further comprise a third tether 8 and a fourth tether 10, which also each comprise a first end coupled to the mass 2 and a second end coupled to the reference 16, and are arranged about the mass 2 to permit movement of the mass 2 within the straightline path relative to the reference 16 to cause the deflection of the tethers thereby resulting in the generation of an electric charge. When the third and fourth tethers 8 and 10 are used, it is preferred that they be coupled to the remaining opposing sides.

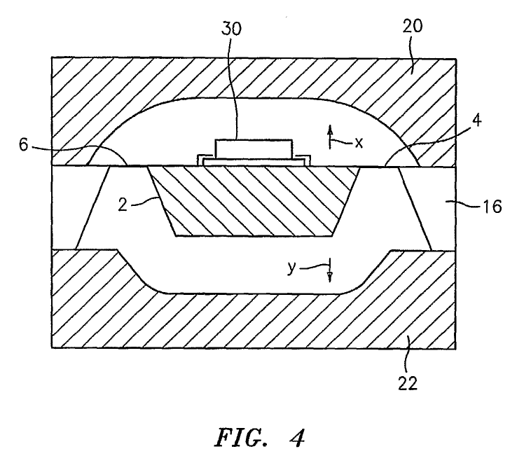

In another embodiment of the invention, the mass when viewed in the top plan view is a polygon having at least three sides and the number of tethers equals the same number of sides of the polygon. Each of the sides of the mass has a first edge and a second edge, and each respective tether has a first end of coupled to the mass at or about the first edge, and extends substantially parallel to, along, and spaced from the side of the mass to which it is coupled, a preferred embodiment of which is illustrated in FIG. 1. The second end of each tether is coupled to the frame at a point on a side of the frame that corresponds to an adjacent side of the mass to permit movement of the mass with the essentially straightline path relative to the frame, as illustrated by arrow(s) “x” and “y” of FIG. 4. The frame also typically has the same number of sides as the mass. This is generally shown in FIG. 1 for a polygon having four sides. However, the invention is not limited to geometries with four sides and is usable with geometries having any number of sides so long as the other features of the invention are also present.

It is generally preferred that the mass not undergo any twisting or rotation during its movement relative to the reference, although precise placement of the piezoelectric material may also recover electrical energy from such movements as well.

The reference 16 to which the at least two tethers 4 and 6 are attached may include a frame that extends substantially from a top surface to a bottom surface of the mass 2, as shown in FIG. 4.

In another embodiment, as depicted in FIG. 4, the energy harvesting device may include a first cap 20 attachable to the frame 16 and extending over the top surface of the mass 2 and/or a second cap 22 attachable to the frame 16 and extending over the bottom surface of the mass 2. The first cap 20 and the second cap 22 are used to protect the device and prevent over-travel of the mass 2 with respect to the frame 16 when moving in the “x” and “y” straightline directions. The second cap 22 is usually positioned a suitable distance from the mass 2 to allow the mass to move within the straightline path relative to the frame 16. The first cap 20 and the second cap 22 are also preferably formulated from a resilient material, which is typically a sufficiently soft polymer. Specific nonlimiting examples include materials such as polydimethylsiloxane (PDMS), resilient polymers, silicon, silicon coated polymers, and combinations of the foregoing.

The energy harvesting device of the invention can be fabricated using standard MEMS fabrication techniques from a silicon-on-insulator (SOI) substrate, which, in one embodiment, comprises a first silicon layer, a silicon dioxide layer on the first silicon layer, and a second silicon layer on the silicon dioxide layer. During fabrication, the tethers may be micromachined from the second silicon layer of the SOI substrate, which is most typically the source of the piezoelectric material. The mass and the reference (i.e., frame) are typically machined from all of the layers of the SOI substrate.

In one example, the first silicon layer has a thickness of about 300-500 μm, the silicon dioxide layer has a thickness of about 2 μm, and the second silicon layer has a thickness of about 5 μm. In this instance, each of the tethers typically has a width of about 10 to about 200 μm, more preferably, a width of about 100 μm. In addition, each of the tethers may be spaced apart from the mass at a suitable distance, which by way of example and not limitation, may be between about 20 to about 500 μm. The thicknesses of the various layers and the layers themselves may be varied as would generally be well known to those skilled in the art.

In static deflection experiments, the devices depicted in FIG. 1 have been repeatedly actuated over 200 μm without causing any structural damage. Thus, in the example described above, the second cap 22 may be placed at least about 100 μm from the bottom surface of the mass 2. This deflection magnitude is more than what is needed to reach maximum stress levels on the piezoelectric thin film.

In another embodiment, the energy harvesting device of the invention includes means for storing the electrical charge generated by the device, which would typically be capacitors and/or batteries, although other means known to those skilled in the art are deemed to be included herein. In one embodiment, the device of the invention includes a capacitor 30 mounted on a top surface of the mass 2.

The energy harvesting device may also have associated therewith at least one sensor or other powerable device (not shown) mounted or fabricated directly on the silicon mass 2 for sensing an external parameter or observing an external condition, by way of example. The type of sensor or device is not critical and may only be limited, if at all, by the amount of energy harvestable by the energy harvesting device. Examples of sensors or other devices that are usable in the practice of the invention include pressure sensors, temperature sensors, humidity sensors, accelerometers, light level sensors, gas sensors, pathogen sensors, cameras, microphones, motion sensors, and combinations of one or more of the foregoing. Other types of sensors or devices would also be known to one skilled in the art and would be usable in the practice of the invention. The sensor or other device may also be remotely activatable to program, activate or retrieve sensed information therefrom.

In a preferred embodiment, the sensor or other powerable device is integrated (e.g. through CMOS circuitry) on the mass itself, although the sensor or other powerable device may merely be electrically coupled to the energy harvesting device (e.g. and spaced therefrom). Integration, however, would result in the most compact system and ultimately provide a more cost-effective device.

In another embodiment, the at least one sensor or other powerable device is physically separated from the energy harvesting device. For example, the energy harvesting device may have an antenna and a wireless (e.g. GHz-range) radio integrated therein or the energy harvesting device may be used in combination with an RFID tag, which is readable by transponders that provide the device with enough energy to relay information to a user.

The communication range of the sensor or other powerable device may range by way of example and not limitation, from a few meters (using simple capacitor storage circuitry and an integrated antenna) to a few-hundred meters (using battery storage and/or in combination with an RFID tag).

Also contemplated by the inventors of the present invention is an energy harvesting system for retrieving sensed or observed information about at least one parameter or condition of interest. Such a system preferably comprises one or more energy harvesting devices as described above, at least one device mounted on the mass or proximate to the one or more energy harvesting devices for sensing an external parameter or observing an external condition and means for retrieving sensed or observed information from the at least one powerable device concerning the desired external parameter or observed external condition.

The present invention is also directed to a method of storing electrical charge in an energy harvesting device comprising a mass; at least two tethers, at least one of which comprises a piezoelectric material that is mechanically stressable upon deflection of the at least two tethers, wherein each of the at least two tethers comprise a first end coupled to the mass and a second end coupled to a reference, wherein the tethers are arranged about the mass such that the mass is moveable within an essentially straightline path relative to the reference wherein the method comprises the steps of:

a) moving the mass to cause the deflection of the at least two tethers and generate an electrical charge; and

b) storing the electrical charge generated by movement of the mass.

In one embodiment, the step of moving the mass is accomplished by subjecting the energy harvesting device to ambient vibrations.

The method may also include the step of sensing at least one external parameter or observing an external condition by associating a sensor or other powerable device on or in connection with (e.g. physically separated from but in close proximity to) the mass that is capable of sensing or monitoring the desired parameter. The step of sensing or monitoring is preferably accomplished by mounting a sensor on the mass that is capable of sensing the desired parameter of the energy harvesting device as discussed above, but having it merely in close physical proximity is also contemplated. Finally it is also contemplated, that the energy harvesting device may be remotely activated to retrieve sensed or monitored information.

It can thus be seen that the present invention provides for significant advancements over the prior art for an energy harvesting device that converts mechanical vibration into electrical energy in response to the stretching and bending of a piezoelectric material. The present invention also provides for advancements over the prior art for providing an improved micro-scale energy harvesting device that can generate significant power, even at lower frequencies.

It is also to be understood that the following claims are intended to cover all of the generic and specific features of the invention described herein and all statements of the scope of the invention which as a matter of language might fall therebetween.

1. An energy harvesting device, comprising:
a mass; and
at least two tethers, at least one of which comprises a piezoelectric material that is mechanically stressable upon deflection of the at least two tethers, wherein each of the at least two tethers comprise a first end coupled to the mass and a second end coupled to a reference, wherein the tethers are arranged about the mass such that the mass is moveable within an essentially straightline path relative to the reference;
whereby the movement of the mass causes the deflection of the at least two tethers thereby resulting in the generation of an electric charge.

2. The energy harvesting device as claimed in claim 1, wherein both of the at least two tethers comprise a piezoelectric material that is mechanically stressable,
whereby the mechanical stress of the piezoelectric material caused by the movement of the mass generates an electric charge.

3. The energy harvesting device as claimed in claim 1, wherein the at two tethers are symmetrically positioned about the mass.

4. The energy harvesting device as claimed in claim 3, wherein the mass, when viewed in a top plan view, has four sides, and wherein the first end of the first tether is coupled to one of the four sides and the first end of the at least second tether is coupled to a side opposing the first side.

5. The energy harvesting device as claimed in claim 4, comprising:
a third tether and a fourth tether, each of which comprise a piezoelectric material that is mechanically stressable upon deflection of its associated tether, wherein each of the third and fourth tethers comprise a first end coupled to the mass and a second end coupled to the reference, wherein the third and fourth tethers are also arranged about the mass to permit movement of the mass within the at least essentially straightline path relative to the reference;
whereby the movement of the mass causes the deflection of the third and fourth tethers thereby resulting in the generation of an electric charge.

6. (canceled)

7. The energy harvesting device as claimed in claim 2, wherein the majority of the mechanical stressing of the piezoelectric material is due to stretching of the material, and wherein the stretching of the piezoelectric material is tensile and the charge generated across the piezoelectric material being stretched is of a single polarity.

8. (canceled)

9. (canceled)

10. The energy harvesting device according to claim 1, wherein the mass, when viewed in a top plan view is a polygon having at least three sides; and
wherein the number of tethers equals the same number of sides of the polygon.

11. The energy harvesting device according to claim 10, wherein each of the sides of the mass has a first edge and a second edge, and wherein each respective tether has a first end of coupled to the mass at or about the first edge, and wherein the tether extends substantially parallel to, along, and spaced from the side of the mass to which it is coupled.

12. The energy harvesting device according to claim 10, including a frame to which the tethers are coupled, wherein the frame extends substantially from a top surface to a bottom surface of the mass, and wherein the frame has the same number of sides as the mass.

13. The energy harvesting device according to claim 12, comprising a first cap attachable to the frame and extending over the top surface of the mass and a second cap attachable to the frame and extending over the bottom surface of the mass, and wherein the second cap is spaced from the mass to allow the mass to move within a straightline path relative to the frame.

14. (canceled)

15. The energy harvesting device according to claim 1, comprising a capacitor mounted on a top surface of the mass.

16. The energy harvesting device according to claim 13, wherein the first cap and the second cap comprise a resilient material selected from the group consisting of polydimethylsiloxane (PDMS), resilient polymers, silicon, silicon coated polymers, and combinations of the foregoing.

17. (canceled)

18. The energy harvesting device according to claim 1, wherein the device is microfabricated from a silicon-on-insulator (SOI) substrate comprising:
a first silicon layer;
a silicon dioxide layer on the first silicon layer; and
a second silicon layer on the silicon dioxide layer.

19. (canceled)

20. The energy harvesting device according to claim 19, wherein the at least two tethers are micromachined from the second silicon layer of the SOI substrate.

21. The energy harvesting device according to claim 19, wherein the mass and the reference are micromachined from all of the layers of the SOI substrate.

22. (canceled)

23. (canceled)

24. (canceled)

25. The energy harvesting device according to claim 1, comprising means for storing the electrical charge generated by the device selected from the group consisting of capacitors and batteries.

26. (canceled)

27. The energy harvesting device according to claim 1, further comprising at least one sensor or powerable device mounted on the mass or proximate to the energy harvesting device for sensing an external parameter or observing an external condition selected from the group consisting of pressure sensors, temperature sensors humidity sensors, accelerometers, cameras, microphones, motion sensors, and combinations of one or more of the foregoing.

28. (canceled)

29. The energy harvesting device according to claim 27, wherein the at least one sensor is remotely activatable to program, activate or retrieve sensed information.

30. The energy harvesting device according to claim 1, wherein the movement of the mass is initiatable by ambient mechanical vibrations.

31. An energy harvesting system for retrieving sensed or observed information about at least one parameter or condition of interest comprising:
a) one or more energy harvesting devices as claimed in claim 1;
b) at least one sensor or powerable device electrically coupled to the one or more energy harvesting devices for sensing an external parameter or observing an external condition; and
c) means for retrieving sensed or observed information from the at least one sensor or powerable device concerning the desired external parameter or observed external condition.

32. An energy harvesting device comprising:
a mass; and
a means coupled to the mass and to a reference, the means comprising a piezoelectric material that is mechanically stressable upon deflection, wherein the means are arranged about the mass such that the mass is moveable within an at least essentially straightline path relative to the reference,
whereby the movement of the mass causes the stressing of the piezoelectric material thereby resulting in the generation of an electric charge.

33. A method of storing an electrical charge in an energy harvesting device comprising a mass; at least two tethers, at least one of which comprises a piezoelectric material that is mechanically stressable upon deflection of the at least two tethers, wherein each of the at least two tethers comprise a first end coupled to the mass and a second end coupled to a reference, wherein the tethers are arranged about the mass such that the mass is moveable within an at least essentially straightline path relative to the reference, wherein the method comprises the steps of:
a) moving the mass to cause the deflection of the at least two tethers and generate an electrical charge; and
b) storing the electrical charge generated by movement of the mass.

34. The method according to claim 33, wherein the step of moving the mass is accomplished by subjecting the energy harvesting device to ambient vibrations.

35. The method according to claim 33, comprising the step of sensing at least one external parameter or observing and external condition by electronically coupling a sensor or powerable device to the energy harvesting device that is capable of sensing or monitoring the desired parameter or condition wherein the at least one parameter to be sensed or observed is selected from the group consisting of pressure temperature humidity acceleration, movement, sound, and combinations of one or more of the foregoing.

36. (canceled)

37. The method according to claim 35, further comprising the step of retrieving, programming and/or activating the sensed or monitored information.
